(19) United States
(12) Patent Application Publication
(10) Pub. No.: US 2016/0155743 A1
(43) Pub. Date: Jun. 2, 2016

(54) Method for Forming Patterns of Semiconductor Device

(71) Applicant: Samsung Electronics Co., Ltd., Suwon-si (KR)

(72) Inventors: Eunsung Kim, Seoul (KR); Seungchul KWON, Suwon-si (KR); Kyoungseon KIM, Suwon-si (KR); Dong-Won KIM, Seongnam-si (KR); Shiyong YI, Seongnam-si (KR)

(21) Appl. No.: 14/956,049

(22) Filed: Dec. 1, 2015

(30) Foreign Application Priority Data
Dec. 2, 2014 (KR) 10-2014-0170799

(51) Int. Cl. H01L 27/105; H01L 21/306; H01L 21/308; H01L 21/768

(52) U.S. Cl. CPC H01L 27/105; H01L 21/76814; H01L 21/76832; H01L 21/76816; H01L 21/30604; H01L 21/3085

(57) ABSTRACT

A method for forming patterns of a semiconductor device includes forming a block copolymer layer on an underlying layer, the underlying layer including a first block copolymer having first and second polymer blocks; phase-separating the block copolymer layer to form first block portions including the first polymer block and a second block portion surrounding the first block portions and including the second polymer block; removing the first block portions to form first openings; forming block copolymer pillars to fill the first openings, the block copolymer pillars including a second block copolymer having third and fourth polymer blocks; phase-separating the block copolymer pillars to form third block portions including the third polymer block and fourth block portions including the fourth polymer block within the first openings; and removing the third block portions to form second openings.

### CROSS-REFERENCE TO RELATED APPLICATIONS

This application claims priority under 35 USC §119 to Korean Patent Application No. 10-2014-0170799, filed on Dec. 2, 2014, the contents of which is hereby incorporated by reference in its entirety.

### BACKGROUND

The present inventive concepts relate to a method for forming patterns of a semiconductor device and, more particularly, to a method for forming patterns of a semiconductor device using a block copolymer.

Recently, in view of the decrease in size of electronic devices and the increase in the degree of integration of semiconductor devices, there has been an increased demand for lithography technologies for forming fine nano-sized patterns. However, conventional photolithography technologies encounter difficulties in the fabrication of nano-sized fine patterns, in particular, nano-sized fine patterns of less than about 20 nm, due to the wavelength resolution limit. Accordingly, various methods based on new principles for fabricating nano-sized fine patterns have been studied. One of these methods utilizes a self-assembled nano-structure.

A block copolymer is a type of a polymeric material that may be self-assembled to form a nano-structure. The molecular structure of the block copolymer typically includes chemically different polymer blocks connected to one another through a covalent bond. Such polymer blocks may be self-assembled to form various repeating nano-sized structures such as a sphere, a cylinder, and a lamella with a period of about 5 to about 50 nm. The size and properties of the nanostructure may be controlled via changing the monomer types, the ratio between the monomers, and a molecular weight of the polymer. In addition, the block copolymer may form nanostructures with a long range order through a parallel process. Since the nanostructure of the block copolymer can be used as an easily removable template, it is becoming attractive as a fine patterning technology for manufacturing various next-generation devices in the information technology (IT), biotechnology (BT), and environmental technology (ET) fields.

### SUMMARY

Exemplary embodiments of the disclosure provide a method for forming patterns of a semiconductor device. In some embodiments, the method may comprise forming a block copolymer layer on an underlying layer, the block copolymer layer including a first block copolymer having first and second polymer blocks; phase-separating the block copolymer layer to form first block portions including the first polymer block and a second block portion surrounding the first block portions and including the second polymer block; removing the first block portions to form first openings; forming block copolymer pillars to fill the first openings, the block copolymer pillars including a second block copolymer having third and fourth polymer blocks; phase-separating the block copolymer pillars to form third block portions including the third polymer block and fourth block portions including the fourth polymer block within the first openings; and removing the third block portions to form second openings.

In exemplary embodiments, the first blocks and the third blocks may each have a cylindrical shape.

In exemplary embodiments, the diameter of the third block portions may be about 0.4 to about 0.6 times that of the first block portions.

In exemplary embodiments, the third block portions may be formed to have a one-to-one correspondence with the first openings.

In exemplary embodiments, the fourth block portions may be formed between the second block portion and the third block portions.

In exemplary embodiments the molar volume ratio between the first polymer block and the second polymer block may be in a range of about 0.2:0.8 to about 0.35:0.65.

In exemplary embodiments, the molar volume ratio between the third polymer block and the fourth polymer block may be in a range of about 0.2:0.8 to about 0.35:0.65.

In exemplary embodiments, the second polymer block has an affinity to the fourth polymer block that may be greater than that between the second polymer block and the third polymer block.

In exemplary embodiments, the first polymer block and the third polymer block may be hydrophilic, and the second polymer block and the fourth polymer block may be hydrophobic.

In exemplary embodiments, the first polymer block and the third polymer block are hydrophobic, and the second polymer block and the fourth polymer block may be hydrophilic.

In exemplary embodiments, the first polymer block and the third polymer block may include the same monomer, and the second polymer block and the fourth polymer block may include the same monomer.

In exemplary embodiments, the second block copolymer has a molecular eight that may be lower than that of the first block copolymer.

In exemplary embodiments, the molecular weight of the second block copolymer may be about 0.2 to about 0.3 times that of the first block copolymer.

In exemplary embodiments, the method may further include forming a neutral layer on the underlying layer before forming the block copolymer layer on the neutral layer and underlying layer. Affinity of the neutral layer to the first polymer block and affinity of the neutral layer to the second polymer block may be substantially equal to each other, and affinity of the neutral layer to the third polymer block and affinity of the neutral layer to the fourth polymer blocks may be substantially equal to each other.

In exemplary embodiments, the method may further comprise forming a mask layer on the underlying layer before forming the block copolymer layer on the mask layer and underlying layer; etching the mask layer using the second block portion and the fourth block portions as an etch mask to form a mask pattern; and patterning the underlying layer using the mask pattern as an etch mask.

In exemplary embodiments, the method may further comprise forming a neutral layer on the mask layer formed on the underlying layer before forming the block copolymer layer on the neutral layer, mask layer and underlying layer; etching the mask layer using the second block portion and the fourth block portions as an etch mask to form a mask pattern; and patterning the underlying using the mask pattern as an etch mask.

In exemplary embodiments, the method may comprise forming a first pattern on an underlying layer, the first pattern having a first opening; forming a block copolymer pillar to fill he first opening; phase-separating the block copolymer pillar to form a pillar pattern and a surrounding pattern, the surrounding pattern having a second opening, the pillar pattern being formed in the second opening; and removing the pillar pattern.

In exemplary embodiments, forming the first pattern may comprise forming a block copolymer layer on the underlying layer; phase-separating the block copolymer layer to form the first pattern and a second pattern, the second pattern being formed in the first opening; and removing the second pattern.

In exemplary embodiments, the second pattern may have pillar structure.

In exemplary embodiments, the surrounding pattern may contact with an inner sidewall of the first opening.

In exemplary embodiments, the present inventive concept provides a semiconductor device, for example, a semiconductor memory device, fabricated according to methods of the present inventive concept.

In exemplary embodiments, the present inventive concept provides electronic systems, for example, devices configured to communicate data wirelessly, and information processing systems, comprising a semiconductor device, such as a semiconductor memory device, fabricated according to methods of the present inventive concept.

According to the foregoing embodiments of the inventive concept, a pattern with improved critical dimension (CD) uniformity may be formed while maintaining periodicity.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain principles of the disclosure. In the drawings:

FIGS. 1A to 8A are top plan views illustrating a method for forming patterns according to an embodiment of the inventive concept.

FIGS. 1B to 8B are cross-sectional views taken along line in FIGS. 1A to 8A, respectively.

FIG. 9 is a top plan view of a semiconductor memory device formed using a hod for forming patterns according to embodiments of the inventive concept.

FIGS. 10 and 11 illustrate a method for fabricating a semiconductor memory device using the method for forming patterns according to embodiments of the inventive concept and are corresponding lines I-I′ and II-II′ in FIG. 9, respectively.

FIG. 12 is a perspective view of a three-dimensional semiconductor memory device formed using the method for forming patterns according to embodiments of the inventive concept.

FIG. 13 is a cross-sectional view of a variable resistance memory device formed using the method for forming patterns according to embodiment of the inventive concept.

FIG. 14 is a block diagram illustrating an example of an electronic system including a semiconductor device formed using a method of forming fine patterns according to embodiments of the inventive concept.

FIG. 15 is a block diagram illustrating another example of an electronic system including a semiconductor device formed using a method for forming fine patterns according to embodiments of the inventive concept.

### DETAILED DESCRIPTION

The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept.

In the specification, it will be understood that when an element is referred to as being “on,” “connected to,” etc., another element, layer or substrate, it can be directly on or connected to the other element, or intervening elements may also be present. It will also be appreciated by those of skill in the art that references to a structure or feature that is disposed “adjacent” another feature may have portions that overlap or underlie the adjacent feature. In the drawings, thicknesses of elements are exaggerated for clarity of illustration.

Exemplary embodiments of the invention will be described below with reference to cross-sectional views, which are exemplary drawings of the invention. The exemplary drawings may be modified by manufacturing techniques and/or tolerances. Accordingly, the exemplary embodiments of the invention are not limited to specific configurations shown in the drawings, and include modifications based on the method of manufacturing the semiconductor device. For example, an etched region shown at a right angle may be formed in a rounded shape or formed to have a predetermined curvature. Therefore, regions shown in the drawings have schematic characteristics. In addition, the shapes of the regions shown in the drawings exemplify specific shapes of regions in an element, and do not limit the invention. Though terms like a first, a second, and a third are used to describe various elements in various embodiments of the inventive concept, the elements are not limited to these terms. These terms are used only to tell one element from another element. An embodiment described and exemplified herein includes a complementary embodiment thereof.

The terms used in the, specification are for the purpose of describing particular embodiments only and are not intended to be limiting of the invention. As used in the specification, the singular forms “a”, “an” and “the” are intended to include the plural forms as well, unless the context clearly indicates otherwise. It will be further understood that the terms “comprises” and/or “comprising”, when used in the specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

It will be understood that although the terms “first,” “second” and “third,” etc. may be used herein to describe various patterns, regions, layers, and/or sections, these patterns, regions, layers, and/or sections should not be limited by these terms. These terms are only used to distinguish one region, layer, or section from another region, layer, or section. Thus, a first region, layer, or section discussed below could be termed a second region, layer, or section, and similarly, a third without departing from the teachings of the present invention. Thus, the terms “first,” “second” and “third,” etc. are not intended to convey a sequence or other hierarchy to the associated elements but are used for identification purposes only. The sequence of operations (or steps) is not limited to the order presented in the claims or figures unless specifically indicated otherwise.

Spatially relative terms, such as “lower,” “bottom,” “upper,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as at the “bottom” would then be on “top.” The device in the figures may be otherwise oriented (rotated 90 degrees or at other orientations) and the spatially relative descriptors used herein interpreted accordingly. Similarly, the terms “uppermost,” “lowermost,” “vertical” and the like are used herein for the purpose of explanation only unless specifically indicated otherwise.

Hereinafter, embodiments of the inventive concept will now be described more fully with reference to accompanying drawings.

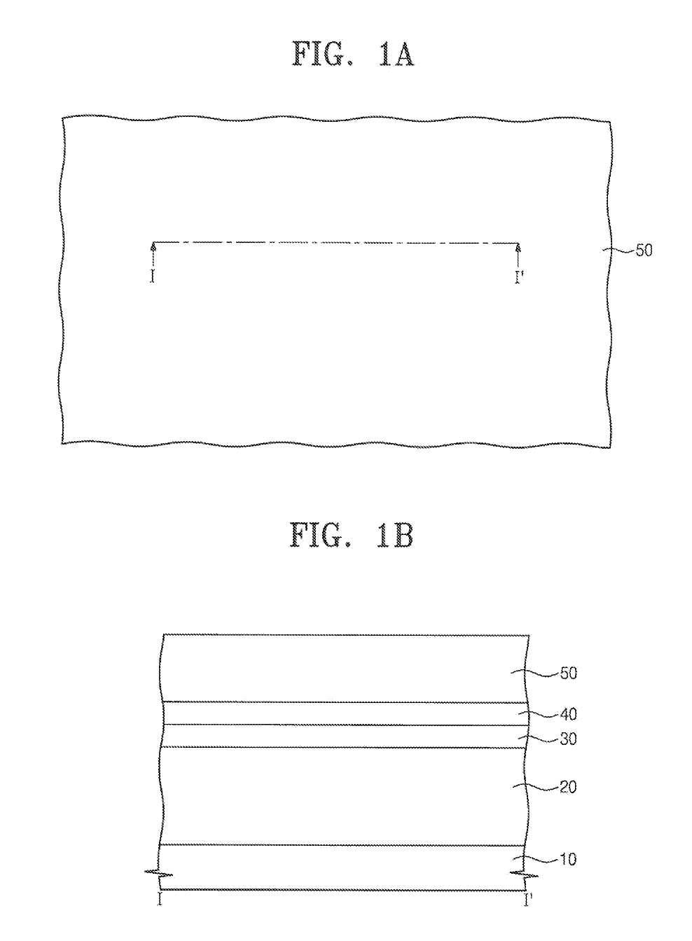

FIGS. 1A to 8A are top plan views illustrating a method for forming patterns according to an embodiment of the inventive concept, FIGS. 1B to 8B are cross-sectional views taken along lines I-I′ in FIGS. 1A to 8A, respectively. Hereinafter, a method for forming patterns according to embodiments of the present inventive concept will now be described with reference to FIGS. 1A to 8A and FIGS. 1B to 8B.

Referring to FIG. 1A and FIG. 1B, an underlying layer 20, a mask layer 30, a neutral layer 40, and a block copolymer layer 50 may be sequentially formed on a substrate 10.

The underlying layer 20 may be formed of one selected from the group consisting of a semiconductor material conductive material, and an insulating material or a combination thereof. For example, the underlying layer 20 may be formed of a semiconductor material including a semiconductor wafer or an epitaxial layer. For example, the underlying layer 20 may be formed of a conductive material including doped polysilicon, metal silicide, a metal, and metal nitride or a combination thereof. For example, the underlying layer 20 may be formed of an insulating material including silicon oxide, silicon nitride, silicon oxynitride or a low-k material. In some embodiments, the underlying layer 20 may be formed of crystalline silicon, amorphous silicon, doped silicon, silicon germanium or a carbon-based material. The underlying layer 20 may be formed to have a single-layered structure or a multi-layered structure. For example, the underlying layer 20 may include a plurality of stacked insulating layers and include conductive layers or semiconductor layers disposed between the stacked insulating layers.

The mask layer 30 may be formed of a material having an etch selectivity with respect to the underlying layer 20. For example, the mask layer 30 may include a spin-on-hardmask (SOH) layer or an amorphous carbon layer (ACL). The SOH layer may include a carbon-based SOH layer or a silicon-based SOH layer. Thickness of the mask layer 30 may vary depending on thickness and material of the underlying layer 20.

The neutral layer 40 may have the same affinity with respect to first and second polymer blocks that will be described later. The expression “having the same affinity with respect to A and B” means “having the same/similar level of surface energy with respect to A and B”. That is, surface energy between the neutral layer 40 and the first polymer block may have substantially the same/similar level as surface energy between the neutral layer 40 and the second polymer block. In addition, the neutral layer 40 may have the same affinity with respect to third and fourth polymer blocks that will be described later. That is surface energy between the neutral layer 40 and the third polymer block may have substantially the same level as surface energy between the neutral layer 40 and the fourth polymer block. The neutral layer 40 may include a neutral self-assembled unimolecular layer or a neutral polymer brush layer. Examples of the neutral self-assembled unimolecular layer may include, but are not limited thereto, phenethyltrichlorosilane (PETCS), phenyltrichlorosilane (PTCS), benzyltrichlorosilane (BZTCS), tolyltrichlorosilane (TTCS), 2-[(trimethoxysilyl)ethyl]-2-pyridine (PYRTMS), 4-biphenylyltrimethoxysilane (BPTMS), octadecyltrichlorosilane (OTS), 1-naphthyltrimethoxysilane (NAPTMS), 1-[(trimethoxysilyl)methyl]naphthalene (MNATMS), (9-methylanthracenyl)trimethoxysilane (MANTMS). Examples of the neutral polymer brush layer may include, for example, a random copolymer including first and second polymer blocks constituting a first block copolymer that will be described later (e.g., PS-r-PMMA when self-assembly of PS-b-PMMA block copolymer is used) and/or a random copolymer including third and fourth polymer blocks constituting a second block copolymer that will be described later.

The block copolymer layer 50 may include the first block copolymer including the first copolymer block and the second polymer block. The first and second polymer blocks may be covalently bonded. The first and second polymer blocks may include different monomers, and accordingly the first and second polymer blocks may have different properties. For example, the first polymer block may be hydrophilic and the second polymer block may be hydrophobic. Alternatively, the first polymer block may be hydrophobic and the second polymer block may be hydrophilic. Examples of the first block copolymer may include, but are not limited thereto, a polystyrene-polymethylmethacrylate block copolymer (PS-b-PMMA), a polystyrene-polymethylacrylate block copolymer(BCP), a polystyrene-polyethylmethacrylate BCP, a polystyrene-poly-t-butyl methacrylate BCP, a polystyrene-polymethacrylic acid BCP, a polystyrene-polybutoxymethacrylate BCP, a polystyrene-polyethylacrylate BCP, a polystyrene-polyacrylic acid BCP, a polystyrene-polybutadiene BCP (PS-b-PBD), a polystyrene-polyisoprene BCP (PS-b-PI), a polystyrene-polyethylenepropylene BCP (PS-b-PEP), a polystyrene-polydimethylsiloxane BCP (PS-b-PDMS), a polystyrene-polyethylene BCP (PS-b-PE), a polystyrene-polyvinylpyridine BCP (PS-b-P4VP), a polystyrene-polyethylene oxide BCP (PS-b-PEO), a polyethylene oxide-polyisoprene BCP (PEO-b-PI), a polyethylene oxide-polybutadiene BCP (PEO-b-PBD), a polyethylene oxide-polymethylmethacrylate BCP (PEO-b-PMMA), a polyethylene oxide-polyethyleneethylene BCP (PEO-b-PEE), a polystyrene-polyferrocyanyldimethylsilane BCP (PS-b-PFS), a polybutadiene-polyvinylpyridine BCP (PBD-b-PVP), a polyisoprene-polymethylmethacrylate BCP (PI-b-PMMA), and a poly2-vinylpyridine-polydimethylsiloxane BCP (P2VP-b-PDMS), but is not limited thereto. The first block copolymer of the block copolymer layer 50 may include first and second polymer blocks that are mixed randomly. However, the first block copolymer may be phase-separated into an area including a first polymer block and another area including a second polymer block by heat treatment. The separated areas may have a spherical, cylindrical, or lamellar structure according to a molar volume ratio of the first and second polymer blocks. For example, when a molar volume ratio between the first and second polymer blocks is in a range of about 0.2:08 to about 0.35:0.65, phase separation may occur such that the area including the first polymer block has a cylindrical shape and the area including the second polymer block has a shape to fill a space between the cylinders. For example, when a molar volume ratio between the first and second polymer blocks is in a range of about 0.4:0.6 to about 0.6:0.4, phase separation may occur such that the area including the first polymer block and the area including the second polymer block have a lamellar structure. When phase separation occurs, the period of the separated areas (e.g., distance between spheres/cylinders or the sum of thicknesses of A and B layers in an ABAB lamellar structure) may vary depending on mean molecular weight of the first block copolymer. That is, the greater the mean molecular weight of the first block copolymer, the greater the period of the separated areas. In addition, the size of a separated phase (e.g., diameter of a sphere, a diameter of a cylinder or thickness of a lamellar layer) may vary depending on the mean molecular weight of the first block copolymer. That is, the greater the mean molecular weight of the first block copolymer, the larger the size of the separated phase.

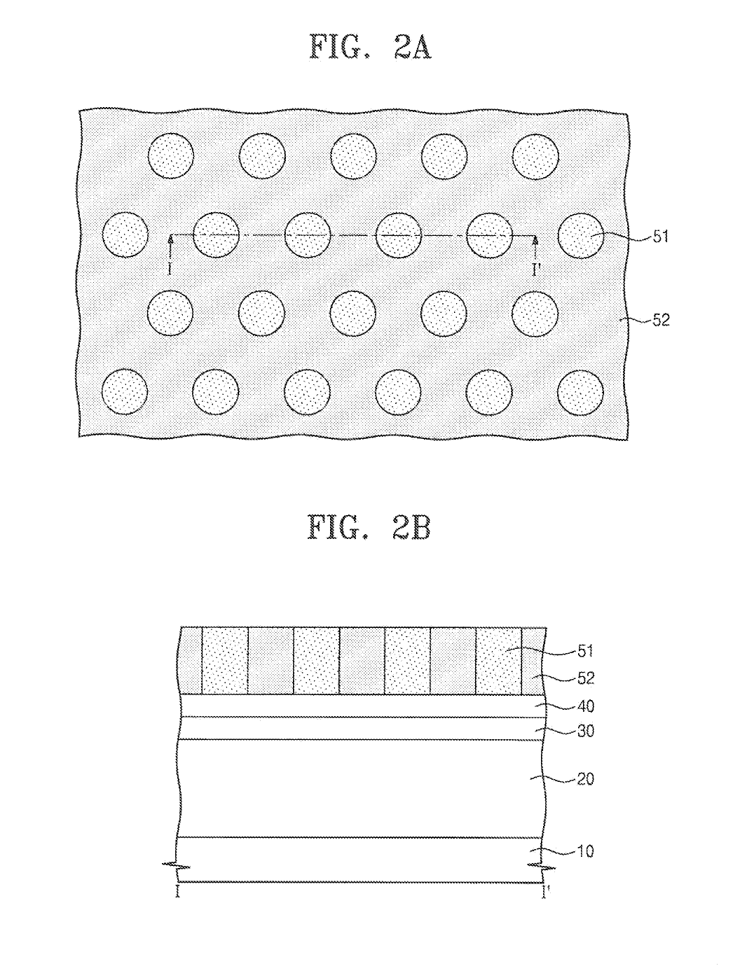

Referring to FIGS. 2A and 2B, first block portions 51 and a second block portion 52 may be formed through phase separation of a block copolymer layer 50 (see FIGS. 1A and 1B). The first block portions 51 may include a first polymer block, and the second block portion 52 may include a second polymer block. The phase separation may be performed by thermally treating the block copolymer layer 50 at a temperature from about 150 to about 350° C. The shapes of the separated first block portions 51 and second block portion 52 may vary depending on a molar volume ratio of the first and second polymer blocks, as described above. When a molar volume ratio between the first and second polymer blocks is in a range of about 0.2:0.8 to about 0.35:0.65, phase separation may occurs such that the first block portions 51 has a cylindrical shape and the second block portion 52 surrounds to the first bock units 51. Since the first polymer block and the second polymer block have the same affinity with respect to a neutral layer 40, the first block portions 51 and the second block portion 52 may be arranged to be perpendicular to the neutral layer 40.

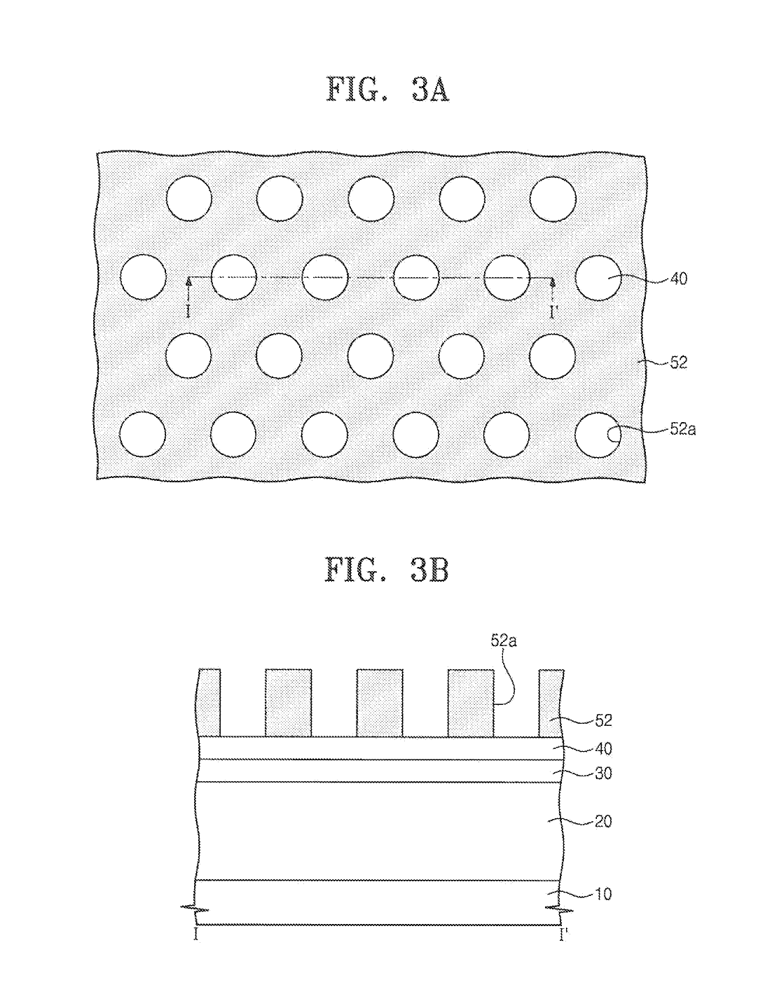

Referring to FIGS. 3A and 3B, first block portions 51 may be removed to form first openings 52a. A neutral layer 40 may be exposed by the first openings 52a. A manner to remove the first block portions 51 is not particularly limited and may be appropriately selected according to a component of the first blocks 51. For example, the first block portions 51 may be removed using oxygen plasma, ozone treatment, UV irradiation treatment, pyrolysis treatment, chemical dissolution treatment or a combination thereof.

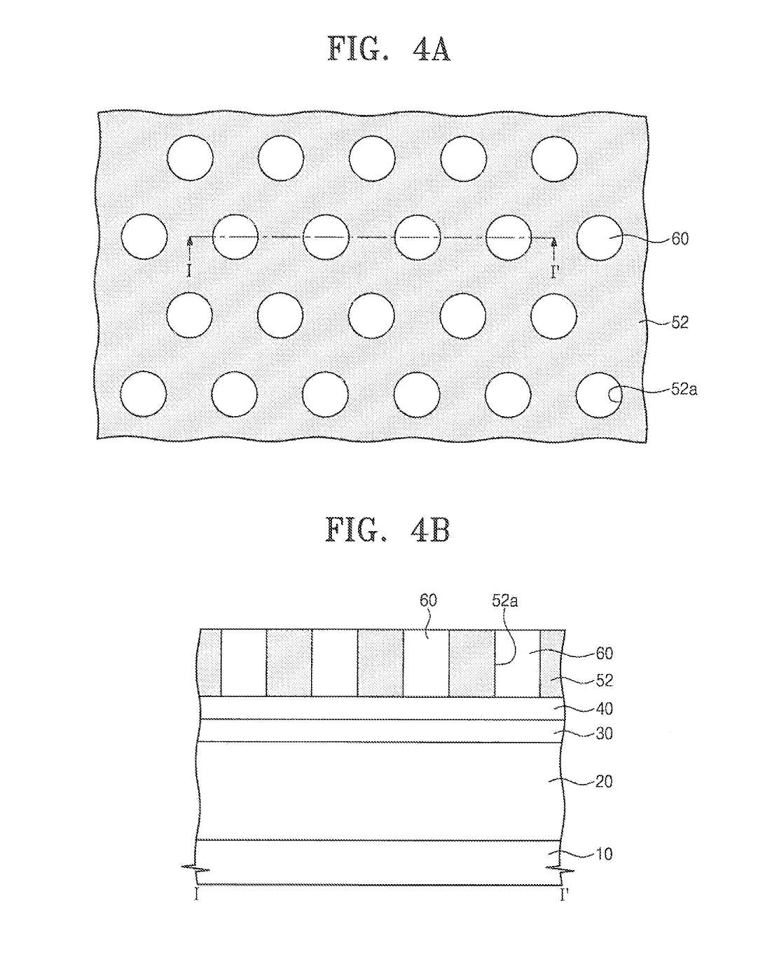

Referring to FIGS. 4A and 4B, block copolymer pillars 60 may be formed to fill first openings 52a. The block copolymer pillars 60 may include a second block copolymer including a third polymer block and a fourth copolymer block. The third and fourth polymer blocks may be covalently bonded. The third and fourth polymer blocks may include different monomers, and accordingly they may have different properties. Affinity between second and fourth polymer blocks may be greater than that between second and third polymer blocks (the expression “affinity between A and B is greater than that between A and C” means that ahead of C, B comes in contact with a surface of A because surface energy between A and B is smaller than surface energy between A and C). In other words, the surface energy between the second and fourth polymer blocks may be smaller than the surface energy between the second and third polymer blocks. In an example embodiment, when the first polymer block is hydrophilic and the second polymer block is hydrophobic, the third polymer block may be hydrophilic and the fourth polymer block may be hydrophobic. In another example embodiment, when the first polymer block is hydrophobic and the second polymer black is hydrophilic, the third polymer block may be hydrophobic and the fourth polymer block may be hydrophilic. In another example embodiment, the first and third polymer blocks may include the same monomer and the second and fourth polymer blocks may include the same monomer. Examples of a second block copolymer may include, but are not limited thereto, a polystyrene polymethylmethacrylate block copolymer (PS-b-PMMA), a polystyrene-polymethylacrylate block copolymer, a polystyrene-polyethylmethacrylate block copolymer, a polystyrene-poly-t-butyl methacrylate block copolymer, polystyrene-polymethacrylic acid block copolymer, a polystyrene-polybutoxymethacrylate block copolymer, a polystyrene-polyethylacrylate block copolymer, a polystyrene-polyacrylic acid block copolymer, a polystyrene-polybutadiene block copolymer (PS-b-PBD), a polystyrene-polyisoprene block copolymer (PS-b-PI), a polystyrene-polyethylenepropylene block copolymer (PS-b-PEP), a polystyrene-polydimethylsiloxane block copolymer (PS-b-PDMS), a polystyrene-polyethylene block copolymer (PS-b-PE), a polystyrene-polyvinylpyridine copolymer (PS-b-P4VP), and a polystyrene-polyethylene oxide block copolymer (PS-b-PEO), a polyethylene oxide-polyisoprene block copolymer (PEO-b-Pi), a polyethylene oxide-polybutadiene block copolymer (PEO-b-PBD), a polyethylene oxide-polymethylmethacrylate block copolymer (PEO-b-PMMA), a polyethylene oxide-polyethylene ethylene block copolymer (PEO-b-PEE), a polystyrene-polyferrocyanyldimethylsilane block copolymer (PS-b-PFS), a polybutadiene-polyvinylpyridine block copolymer (PBD-b-PVP), a polyisoprene-polymethylmethacrylate block copolymer (PI-b-PMMA), and a poly-2-vinylpyridine-polydimethylsiloxane block copolymer (P2VP-b-PDMS). The second block copolymer of the block copolymer pillars 80 may include third and fourth copolymer blocks that are mixed randomly. However, the second block copolymer may be phase-separated into an area including the third polymer block and an area including the fourth polymer block by heat treatment. The separated areas may have a spherical, cylindrical or lamellar structure according to a molar volume ratio of the third and fourth polymer blocks. When phase separation occurs, the period of the separated areas (e.g., distance between spheres/cylinders or the sum of thicknesses of A and B layers in an ABAB lamellar structure) may vary depending on mean molecular weight of the second block copolymer. That is the greater the mean molecular weight of the second block copolymer, the greater the period of the separated areas. In addition, a size of a separated phase (e.g., diameter of a sphere, a diameter of a cylinder, or thickness of a lamellar layer) may vary depending on the mean molecular weight of the second block copolymer. That is, the greater the mean molecular weight of the second block copolymer, the larger a size of the separated phase.

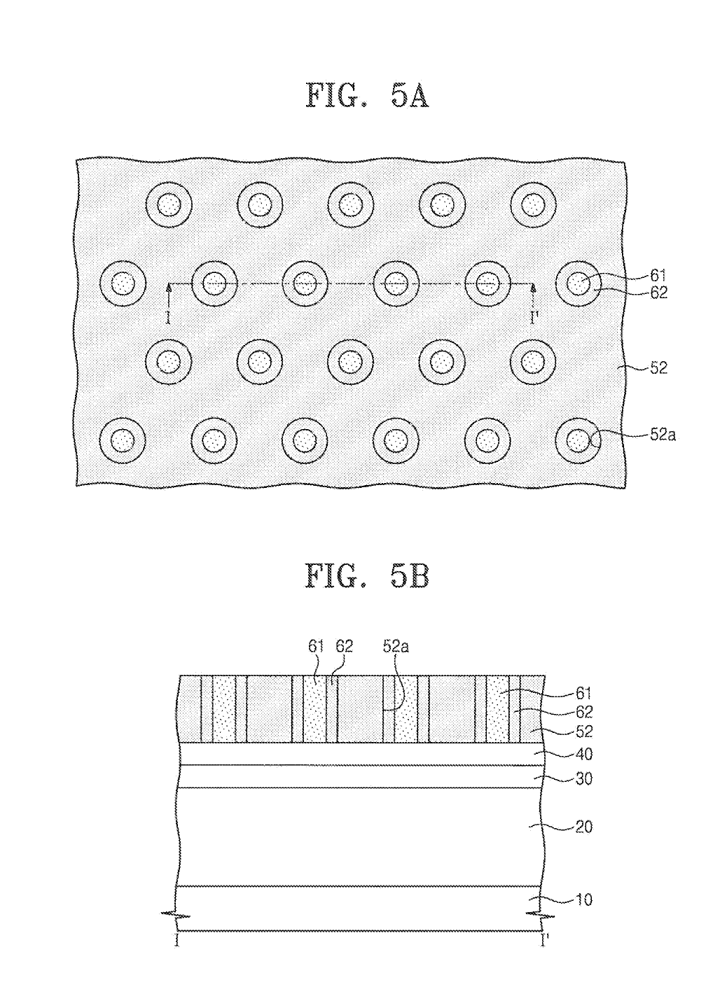

Referring to FIGS. 5A and 5B, third block portions 61 and fourth block portions 62 may be formed through phase separation of block copolymer pillars 60 (see FIGS. 4A and 4B). The third blocks 61 may include a third polymer block, and the fourth blocks 62 may include a fourth polymer block. The phase separation may be performed by thermally treating block copolymer pillars 60 (see FIGS. 4A and 4B) at a temperature from about 150 to about 350° C. Since affinity between second and fourth polymer blocks is greater than affinity between second and third polymer blocks, the fourth block portions 62 may be formed to be in contact with a sidewall of the second block portion 52. The shapes of the separated third and fourth blocks 61 and 62 may vary depending on a molar volume ratio of the third and fourth polymer blocks, as described above. When a molar volume ratio between the third and fourth polymer blocks is in a range of about 0.2:0.8 to about 0.35:0.65, phase separation occurs such that the third blocks 61 has a cylindrical shape and the fourth blocks 62 surrounds the third blocks 61. Since the third and fourth polymer blocks have the same affinity with respect to a neutral layer 40, they may be arranged to be perpendicular to the neutral layer 40. Since a distance between the third blocks 61 and a size of the third blocks 61 vary depending on mean molecular weight of the second block copolymer, the number of third blocks 61 formed within a single first opening 52a may vary depending on the mean molecular weight of the second block copolymer. Thus, the single third block portion 61 may be formed within the single first opening 52a by adjusting the mean molecular weight of the second block copolymer, as shown in FIGS. 5A and 5B. In this case, the fourth block portions 62 may be formed between the second block portion 52 and the third block portions 61, and a diameter of the third block portions 61 may be about 0.4 to about 0.6 times that of first block portions 51 (see FIGS. 2A and 2B). In an example embodiment, when the first and third polymer blocks include the same monomer (e.g., poly(methylmethacrylate)) and the second and fourth polymer blocks include the same monomer (e.g., polystyrene), the single third block portion 61 may be formed within the single first opening 52a by adjusting molecular weight of the second block copolymer to about 0.2 to about 0.3 times that of the first block copolymer.

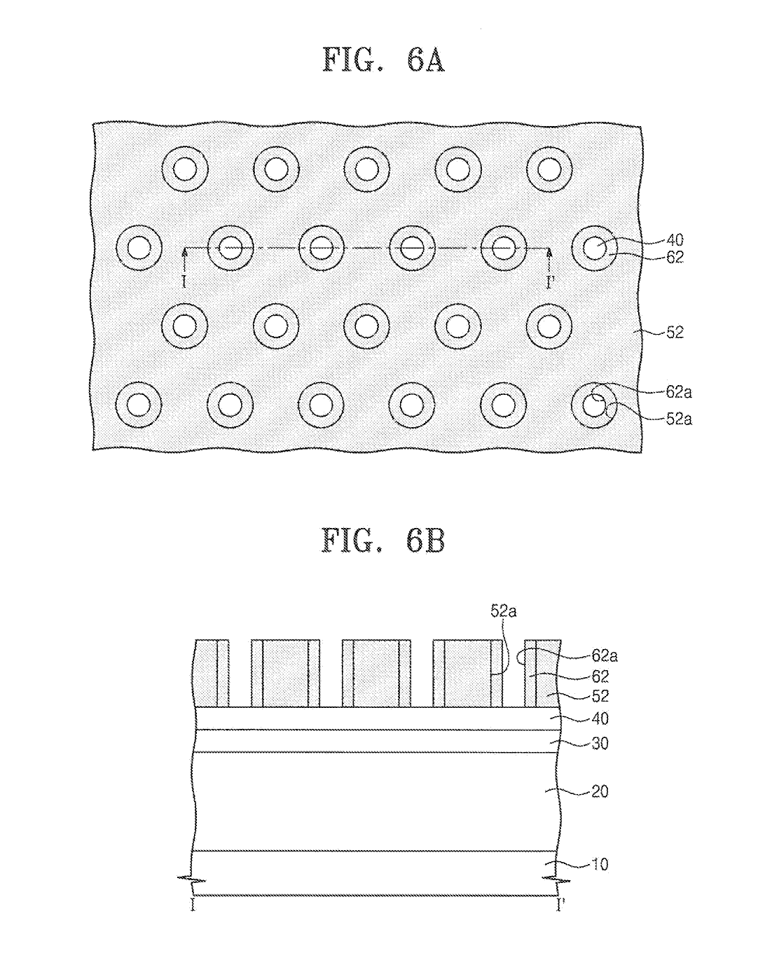

Referring to FIGS. 6A and 6B, third block portions 61 may be removed to form second openings 62a. A neutral layer 40 may be exposed by the second openings 62a. The manner in which the third block portions 61 are removed is not particularly limited and may be appropriately selected according to a component of the third blocks 61. For example, the third block portions 61 may be removed using oxygen plasma, ozone treatment, UV irradiation treatment, pyrolysis treatment, chemical dissolution treatment or a combination thereof.

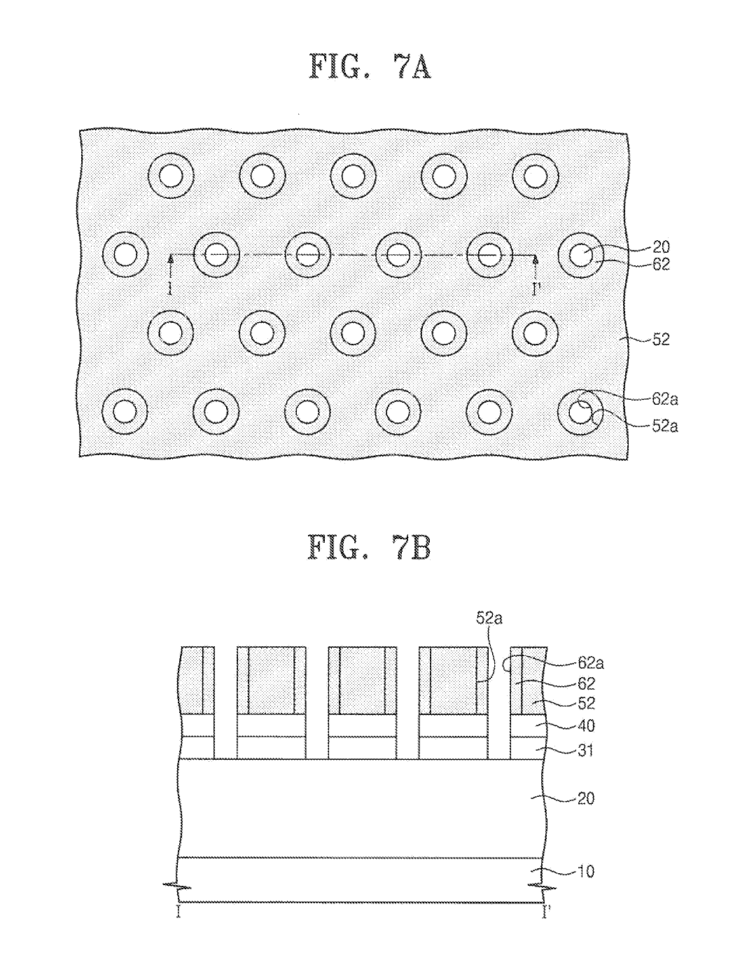

Referring to FIGS. 7A and 78, a mask pattern 31 may be formed by etching a mask layer 30 (see FIGS. 6A and 68) using the second block portions 52 and the fourth block portions 62 as an etch mask. That is, the mask pattern 31 may be formed by etching the mask layer 30 exposed by the second openings 62. At this point, the neutral layer 40 exposed by the second openings 62a may be also etched.

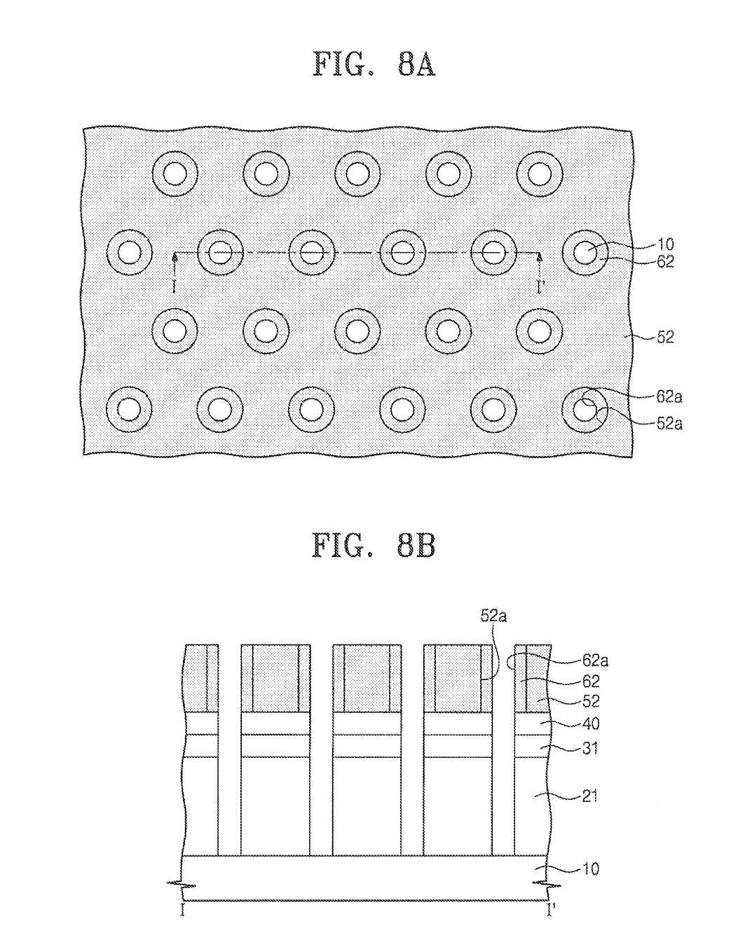

Referring to FIGS. 8A and 88, a lower pattern 21 may be formed by etching a lower layer 20 (see FIGS. 7A and 78) using the mask pattern 31 as an etch mask.

As described above, the second openings 62a may have the same period as the first openings 52a while having higher CD uniformity than the first openings 52a. Thus, the mask pattern 31 and the lower pattern 21 formed using the second openings 62a may have the same period as a mask pattern and a lower pattern formed using the first openings 52a while having higher CD uniformity than the mask pattern and the lower pattern formed using the first openings 52a.

Hereinafter, detailed descriptions will be made with respect to a method for fabricating a semiconductor device using a method for forming patterns according to embodiments of the inventive concept. A semiconductor device mentioned in this specification includes a highly integrated semiconductor memory device such as a dynamic random access memory (DRAM), a static RAM (SRAM), a phase change RAM (PRAM), as resistance RAM (RRAM), a magnetic RAM (MRAM), a ferroelectric RAM (FRAM), and a flash memory, a micro-electro-mechanical systems (MEMS) device, an optoelectronic device or a processor such as CPU and DSP. A semiconductor device may include only the same type of semiconductor devices or may be a single chip data processing device including different types of semiconductor devices necessary for providing a complete function.

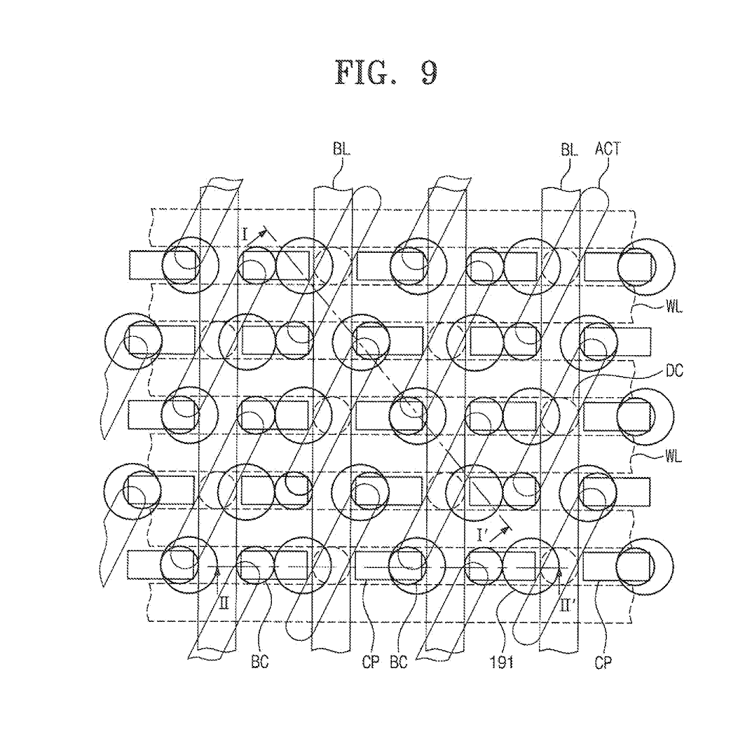

Hereinafter, a semiconductor memory device fabricated using a method for forming patterns according to an embodiment of the inventive concept will be described with reference to FIGS. 9 to 11.

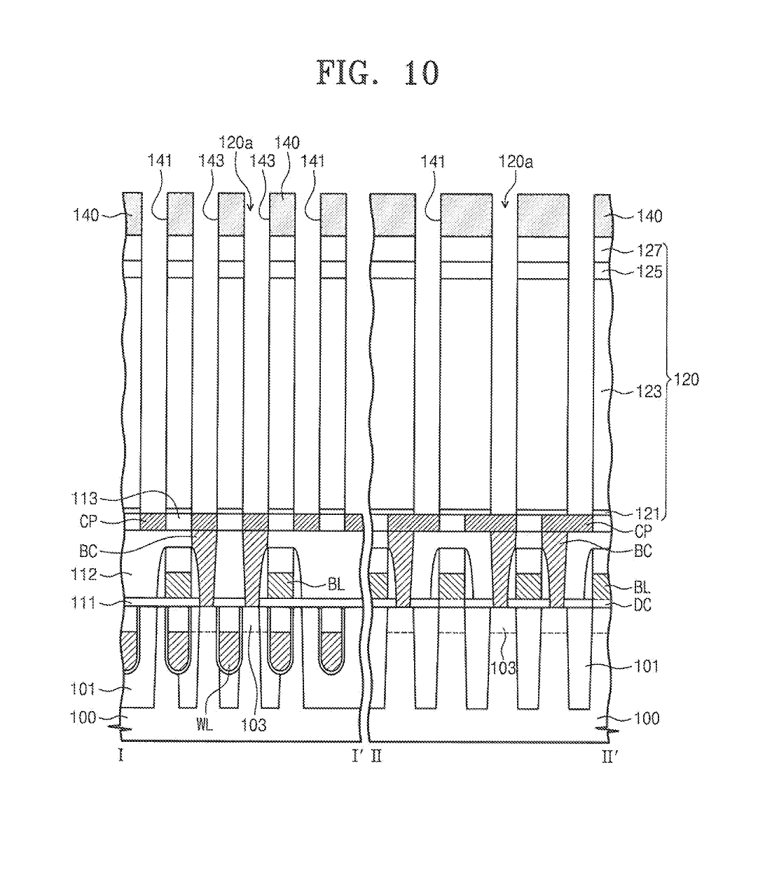

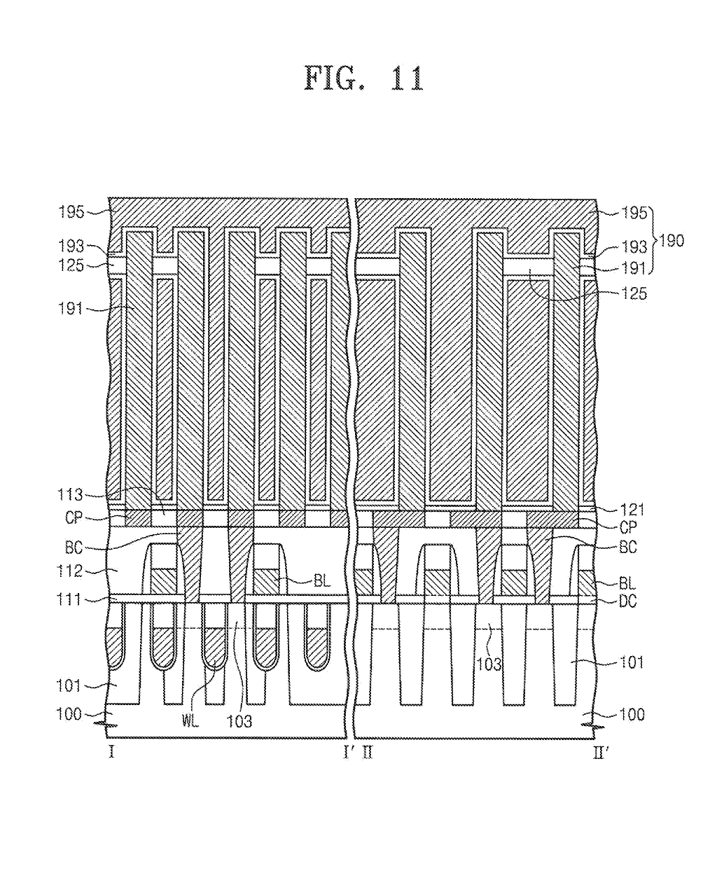

FIG. 9 is a top plan view of a semiconductor memory device formed using a method for forming patterns according to embodiments of the inventive concept. FIGS. 10 and 11 illustrate a method for fabricating a semiconductor memory device using the method for forming patterns according to embodiments of the inventive concept and are corresponding lines I-I′ and II-II′ in FIG. 9, respectively.

Referring to FIGS. 9 and 10, a semiconductor memory device includes wordlines WL and bitlines BL perpendicular to each other and includes memory cells disposed at intersections of the wordlines WL and the bitlines BL.

More specifically, a device isolation layer 101 is formed on a semiconductor substrate 100 to define active regions ACT. The active regions ACT may be bar-shaped, and a long axis of the active regions ACT may be disposed in a direction diagonal to the wordlines WL and the bitlines BL.

The wordlines WL may be disposed to intersect the active regions ACT. In an embodiment, the wordlines WL may be formed in a recess region recessed from a surface of the semiconductor substrate 100 by predetermined depth with a gate insulating layer interposed therebetween. The top surface of the wordlines WL may be disposed at a lower level than the top surface of the semiconductor substrate 100, and an insulating material fills in the recessed region in which a wordline WL is formed.

Source and drain regions 103 may be formed in the active regions ACT adjacent to opposite sides of the wordlines WL. The source and drain regions 103 may be impurity regions doped with impurities.

As the wordlines WL and the source and drain regions 103 are formed, a plurality of MOS transistors may be formed on the semiconductor substrate 100.

The bitlines BL may be disposed on the semiconductor substrate 100 across the wordlines WL. A first interlayer dielectric 111 may be disposed between the bitlines BL and the semiconductor substrate 100, and bitline contact plugs DC may be formed at the first interlayer dielectric 111 to electrically connect the source and drain regions 103 to the bitline BL.

A second interlayer dielectric 112 is formed to cover the bitlines BL. Contact plugs BC may be formed in the second interlayer dielectric 112 to electrically connect a data storage component to the source and drain regions 103. In an embodiment, the contact plugs BC may be disposed on the active region ACT adjacent to opposite sides of the bitline BL.

The contact plugs BC may be formed by forming contact holes in the second interlayer dielectric 112 to expose the source and drain regions 103, depositing a conductive layer to fill the contact hole, and polarizing the conductive layer. The contact plug BC may be formed of at least one of doped polysilicon, metal, metal nitride, metal silicide or a combination thereof.

In an embodiment, contact pads CP may be formed on the contact plugs BC, respectively. The contact pads CP may be two-dimensionally disposed on the second interlayer dielectric 112 and increase a contact area between a bottom electrode of an overlying capacitor and the contact plugs BC. Specifically, the contact pads CP may have a shape where two contact pads extend in opposite directions with a bitline BL interposed therebetween.

A mold layer 120 may be formed on a third interlayer dielectric 113 where the contact pads CP are formed. Thickness of the mold layer 120 may vary depending on height of a bottom electrode of a cylindrical capacitor.

In an embodiment, the mold layer 120 may include an etch-stop layer 121, a lower mold layer 123, a support layer 125, and an upper mold layer 127 that are stacked, in the order named. The lower and upper mold layers 123 and 127 may be formed of silicon oxide, and the etch-stop layer 121 and the support layer 125 may be formed of a material having an etch selectivity with respect to the lower and upper mold layers 123 and 127 during a process of dry-etching the mold layers 120. For example, the etch-stop layer 121 and the support layer 126 may be formed of silicon nitride.

Referring to FIG. 10, first and second openings 141 and 143 may be formed using a mask layer 140 formed according to embodiments of the inventive concept. The mold layer 120 may be etched using the mask layer 140 with the first and second openings 141 and 143 as an etch mask. Thus, lower holes 120a may be formed in the mold layer 120 to expose the contact pads CP.

Referring to FIGS. 9 and 11 with FIG. 10, bottom electrodes 191 may be formed within the lower holes 120a. A cylindrical bottom electrode 191 may be formed in each of the lower holes 120a by conformally depositing a conductive layer along the inner wall of the lower hole 120a and removing the conductive layer deposited on the mold layer 120. Thus, the bottom electrode 191 may be formed to be electrically connected to the contact pads CP. The bottom electrodes 191 may be arranged zigzag or in the form of a honeycomb. After formation of the bottom electrodes 191, the lower and upper mold layers 123 and 125 may be selectively removed to expose sidewalls of the bottom electrodes 191. A dielectric layer 193 may be formed to conformally cover surfaces of the bottom electrodes 191. A top electrode 195 may be formed on the dielectric layer 193. As a result, a capacitor 190 including the bottom electrode 191, the top electrode 195, and the dielectric layer 193 disposed therebetween may be formed.

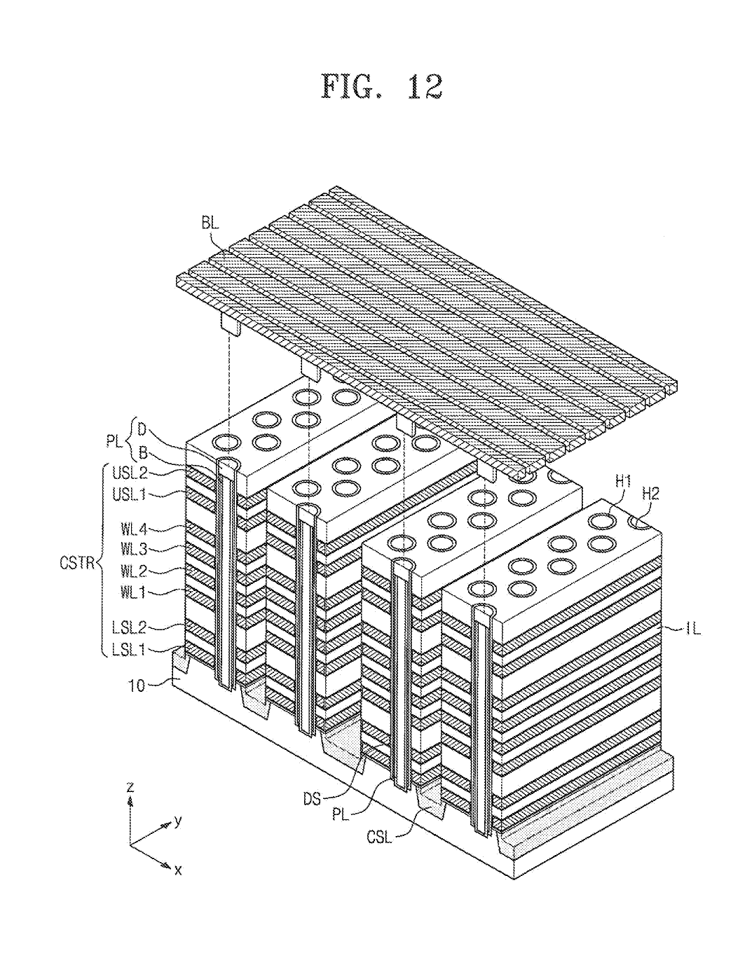

FIG. 12 is a perspective view of a three-dimensional semiconductor memory device formed using the method for forming patterns according to embodiments of the inventive concept.

Referring to FIG. 12, a three-dimensional semiconductor memory device according to an embodiment of the inventive concept may include a common source line CSL, a plurality of bitlines BL, and a plurality of cell strings CSTR disposed between the common source line CSL and the bitlines BL.

The common source line CSL may be a conductive thin film disposed on a substrate 10 or an impurity region formed in the substrate 10. The bitlines BL may be conductive patterns (e.g., metal lines) spaced apart from the substrate 10 to be disposed thereon. The bitlines BL may be two-dimensionally arranged, and a plurality cell strings CSTR may be connected in parallel to the bitlines BL, respectively. Thus, the cell strings CSTR may be two-dimensionally arranged on the common source line CSL or the substrate 10.

Each of the cell strings CSTR may include a plurality of lower selection lines LSL1 and LSL2, a plurality of wordlines WL1 to WL4, and a plurality of upper selection lines USL1 and USL2 disposed between the common source line CSL and the bitlines BL. The lower selection lines LSL1 and LS2, the wordlines WL1 to WL4, and the upper selection lines USL1 and USL2 may be conductive patterns stacked on the substrate 10 with insulating layers IL interposed therebetween.

Each of the cell strings CSTR may include a semiconductor pillar PL extending vertically from the substrate 10 to be connected to the bitline BL. The semiconductor pillars PL may be formed to penetrate the lower selection lines LSL1 and LSL2, the wordlines WL1 to WL4 and the upper selection lines USL1 and USL2. In other words, the semiconductor pillars may penetrate a plurality of conductive patterns stacked on the substrate 10. The semiconductor pillar PL may include a body portion B and impurity regions formed at one end or both ends of the body portion B. For example, a drain region D may be formed at the upper end of the semiconductor pillar PL (i.e. between the body portion B and the bitline BL).

A data storage layer DS may be disposed between the wordlines WL1 to WL4 and the semiconductor pillars PL. In an embodiment, the data storage layer DS may be a charge storage layer. For example, the data storage layer DS may include one of a trap insulating layer, a floating gate electrode, and an insulating layer including conductive nanodots.

A dielectric layer used as a gate insulating layer of a transistor may be disposed between the lower selection lines LSL1 and LSL2 and the semiconductor pillar PL or between the upper selection lines USL1 and USL2 and the semiconductor pillar PL. The dielectric layer may be formed of the same material as the data storage layer DS and may be a gate insulating layer (e.g., silicon oxide layer) for a conventional MOSFET.

In the above structure, the semiconductor pillars PL may constitute a MOS field effect transistor (MOSFET) using the semiconductor pillar PL as a channel region together with the lower selection lines LSL1 and LSL2, the wordlines WL1 to WL4, and the upper selection lines USL1 and USL2. Alternatively, the semiconductor pillars PL may constitute a MOS capacitor together with the lower selection lines LSL1 and LSL2, the wordlines WL1 to WL4, and the upper selection lines USL1 and USL2. That is, the cell string CSTR may have a structure where lower and selection transistors constituted by the lower and upper selection lines LSL1, LSL2, USL1, and USL2 and cell transistors constituted by the wordlines WL1 to WL4 are connected in series.

In the above-described three-dimensional semiconductor memory device including semiconductor pillars PL, the semiconductor pillars PL may be formed using a method for forming patterns according to embodiments of the inventive concept.

More specifically, a stack structure may be formed on the substrate 10. The stack structure may include insulating layers IL and conductive layers such as the lower selection lines LSL1 and LSL2, the wordlines WL1 to WL4, and the upper selection lines USL1 and USL2 that are alternately stacked. The stack structure may correspond to an underlying layer described with reference to FIGS. 1B to 8B. Holes H1 and H2 may be formed in the stack structure using a mask layer having first and second openings. The mask layer having the first and second openings may be formed in the same or similar manner as described with reference to FIGS. 1A to 8A and FIGS. 1B to 8B. A data storage layer DS and semiconductor pillars PL may be formed within the holes H1 and H2.

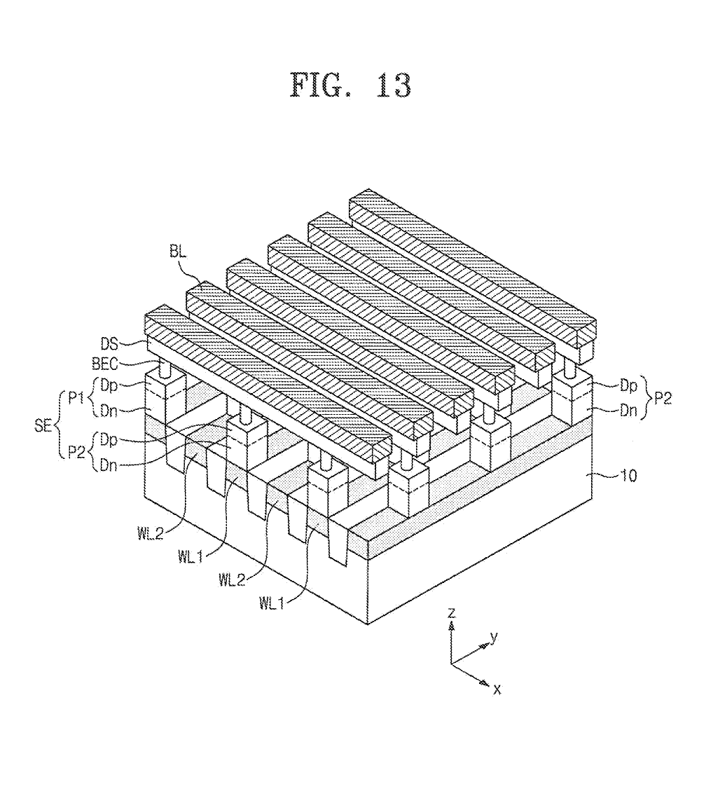

FIG. 13 is a cross-sectional view of a variable resistance memory device formed using the method for forming patterns according to embodiment of the inventive concept.

Referring to FIG. 10, a semiconductor memory device may include a semiconductor substrate 10, lower interconnection WL1 and WL2 on the semiconductor substrate 10, upper interconnections BL intersecting the lower interconnections WL1 and WL2, selection elements SE respectively disposed at intersections of the lower interconnections WL1 and WL2 and the upper interconnections BL, and memory elements DS between the selection elements SE and the upper interconnections BL. The selection elements SE may be two-dimensionally arranged on the semiconductor substrate 10 and may control the flow of current passing through the memory element.

More specifically, the lower interconnections WL1 and WL2 may be a line extending on the semiconductor substrate 10 in a y-axis direction. In an embodiment, the lower interconnections WL1 and WL2 may be an impurity region formed by heavily doping impurities into the semiconductor substrate 10. The lower interconnections WL1 and WL2 may have a conductivity type opposite to that of the semiconductor substrate 10.

In this embodiment, the selection elements SE may include semiconductor patterns P1 and P2 formed using methods for forming patterns according to embodiments of the inventive concept. That is, the semiconductor patterns P1 and P2 may be formed using a mask layer, such as a mask layer having openings formed by methods for forming patterns according to embodiments of the inventive concept, as an etch mask.

The first and second semiconductor patterns P1 and P2 may include an upper impurity region Dp and a lower impurity region Dn, respectively and may have opposite conductivity types. For example, the lower impurity region Dn may have the same conductivity type as the lower interconnections WL1 and WL2, and the upper impurity region Dp may have a conductivity type opposite to that of the lower impurity region Dn. Thus, PN junctions may be formed in the first and second semiconductor patterns P1 and P2, respectively. Alternatively, an intrinsic region may be interposed between the upper impurity region Dp and the lower impurity region Dn to form a PIN junction in the first and second semiconductor patterns P1 and P2. A PNP-type or NPN-type bipolar transistor may be implemented by the semiconductor substrate 10, the lower interconnections WL1 and WL2, and the first and second semiconductor patterns P1 and P2.

Bottom electrodes BEC, memory elements DS, and upper interconnections BL are disposed on the first and second semiconductor patterns P1 and P2. The upper interconnections BL may intersect the lower interconnections WL1 and WL2 and may be electrically connected to the memory elements DS on the memory elements DS.

In an embodiment, the memory elements DS may be formed parallel to the upper interconnections BL, respectively. Each of the memory elements DS may be connected to the plurality of bottom electrodes BEC. Alternatively, the memory elements DS may be two-dimensionally arranged. That is, each of the memory elements DS may be disposed on the respective first and second semiconductor patterns P1 and P2. As described above, the memory elements DS may be a variable resistance pattern that is switchable between two resistance states by an electric pulse applied to a memory element. In an embodiment, the memory element DS may include a phase-change material whose crystalline state is changed by the amount of current. In another embodiment, the memory element DS may include perovskite compounds, transition metal oxide, magnetic materials, ferromagnetic materials or antiferromagnetic materials, instead of the phase-change material,

Each of the bottom electrodes BEC may be disposed between each of the first and second semiconductor patterns P1 and P2 and one of the memory elements DS. The horizontal area of the bottom electrode BEC may be smaller than the horizontal area of the first and second semiconductor patterns P1 and P2 or a horizontal area of the memory element DS.

In an embodiment, each of the bottom electrodes BEC may have a pillar shape. In another embodiment, a shape of each of the bottom electrodes BEC may be variously modified to reduce a sectional area of the bottom electrode BEC. For example, each of the bottom electrodes BEC may be a three-dimensional structure such as a U-shaped structure, an L-shaped structure, a hollow cylindrical structure, a ring-shaped structure, and a cup-shaped structure.

Furthermore, in another embodiment, an ohmic layer may be disposed between the bottom electrodes BEC and the first and second semiconductor patterns P1 and P2 to reduce contact resistance. For example, the ohmic layer may include metal silicide such as titanium silicide, cobalt silicide, and tungsten silicide.

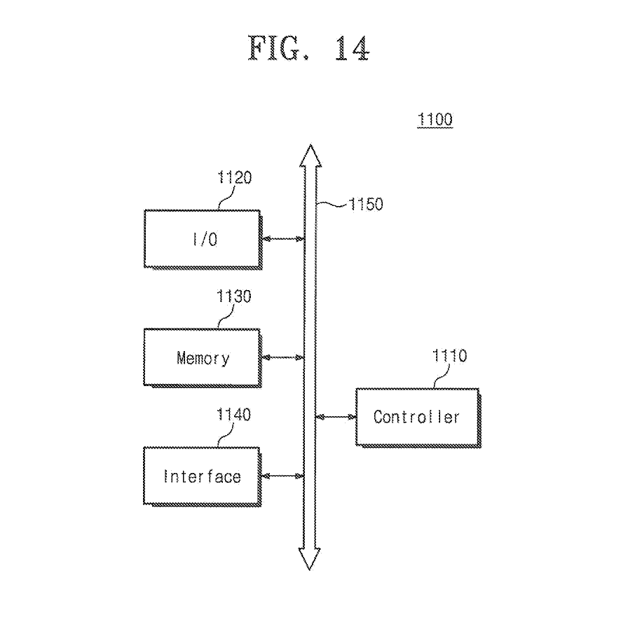

FIG. 14 is a block diagram illustrating an example of an electronic system including a semiconductor device formed using a method of forming fine patterns according to embodiments of the inventive concept.

Referring to FIG. 14, an electronic system 1100 according to an embodiment of the inventive concept may include a controller 1110, an input/output (I/O) device 1120, a memory device 1130, an interface 1140, and a bus 1150. The controller 1110, the 110 device 1120, the memory device 1130, and/or the interface 1140 may be connected to each other through the bus 1150. The bus 1150 corresponds to a path along which data are transmitted. The controller 1110, the I/O device 1120, the memory device 1130, and/or the interface 1140 may include a semiconductor device formed using a method for forming fine patterns according to embodiments of the inventive concept.

The controller 1110 may include at least one of a microprocessor, a digital signal processor, a microcontroller, or logic elements capable of performing similar functions to those of the above elements. The I/O device 1120 may include a keypad, a keyboard, and a display device. The memory device 1130 may store data and/or commands. The interface 1140 may transmit data to a communication network or receive data from the communication network. The interface 1140 may be in a wired or wireless form. For example, the interface 1140 may include an antenna or a wired/wireless transceiver. Although not shown in this drawing, the electronic system 1100 may further include a high-speed dynamic random access memory (DRAM) device and/or a high-speed static random access memory (SRAM) device as a working memory device to improve the operation of the controller 1110.

The electronic system 1100 can be applied to a personal digital assistant (PDA), a portable computer, a web tablet, a wireless phone, a mobile phone, a digital music player, a memory card, and any electronic products that can transmit and/or receive information wirelessly.

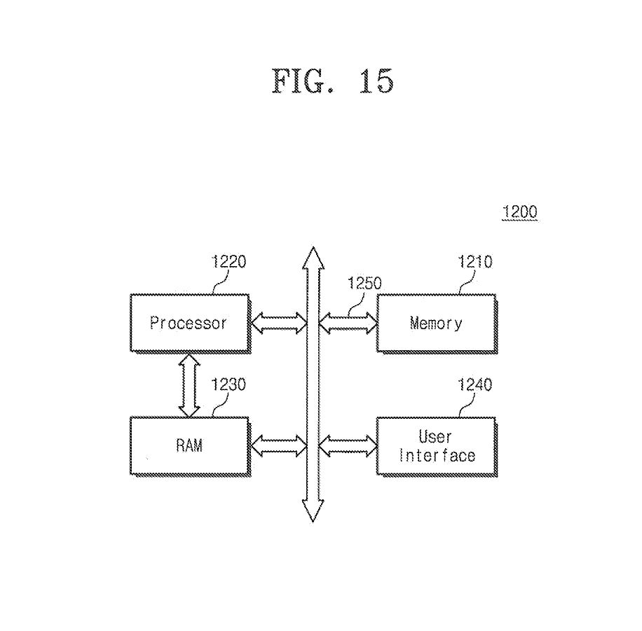

FIG. 15 is a block diagram illustrating another example of an electronic system including a semiconductor device formed using a method for forming fine patterns according to embodiments of the inventive concept.

Referring to FIG. 15, an electronic system 1200 may include at least one semiconductor device formed using a method for forming fine patterns according to embodiments of the inventive concept Examples of the electronic system 1200 include but are not limited to a mobile device, a computer or the like. For example, the electronic system 1200 may include a memory system 1210, a processor 1220, a RAM 1230, and a user interface 1240 which may perform data communication with each other using a bus 1200. The processor 1220 may serve to execute a program and control the electronic system 1200. The RAM 1230 may be used as a working memory of the processor 1220. For example, the processor 1220 and the RAM 1230 may each include a semiconductor device formed using a method for forming fine patterns according to embodiments of the inventive concept. Alternatively, the processor 1220 and the RAM 1230 may be included in a single package. The user interface 1240 may be used to input or output data to the electronic system 1200. The memory system 1210 may store a code for the operation of the processor 1220, data processed by the processor 1200 or externally input data. The memory system 1210 may include a controller or a memory.

The electronic system 1200 may be implemented as a mobile system, a personal computer, an industrial computer or a multi-functional logic system. For example, the mobile system may be one of a personal digital assistant (PDA), a portable computer, a web tablet, a mobile phone, a wireless phone, a laptop computer, a memory card, a digital music system or an information transmitting/receiving system. If the electronic system 1200 is an apparatus capable of performing wireless communication, the electronic system 1200 may be used in a communication interface protocol such as a third-generation communication system (e.g., CDMA, GSM, NADC, E-TDMA, WCDMA, CDMA2000, etc.).

While the present disclosure has been particularly shown and described with reference to exemplary embodiments thereof, the general inventive concept is not limited to the above-described embodiments. It will be understood by those of ordinary skill in the art that various changes and variations in form and details may be made therein without departing from the spirit and scope of the inventive concept as defined by the following claims.

What is claimed is:

1. A method for forming patterns of a semiconductor device, comprising:
forming a block copolymer layer on an underlying layer, the block copolymer layer comprising a first block copolymer having first and second polymer blocks;
phase-separating the block copolymer layer to form first block portions comprising the first polymer block and a second block portion surrounding the first block portions and comprising the second polymer block;
removing the first block portions to form first openings;
forming block copolymer pillars to fill the first openings, the block copolymer pillars comprising a second block copolymer having third and fourth polymer blocks;
phase-separating the block copolymer pillars to form third block portions comprising the third polymer block and fourth block portions comprising the fourth polymer block within the first openings; and
removing the third block portions to form second openings.

2. The method of claim 1, wherein the first blocks and the third blocks each have a cylindrical shape.

3. The method of claim 2, wherein a diameter of the third block portions is about 0.4 to about 0.6 times that of the first block portions.

4. The method of claim 1, wherein the third block portions are formed to have one-to-one correspondence with the first openings.

5. The method of claim 4, wherein the fourth block portions are formed between the second block portion and the third block portions.

6. The method of claim 1, wherein a molar volume ratio between the first polymer block and the second polymer block is in a range of about 0.2:0.8 to about 0.35:0.65.

7. The method of claim 1, wherein a molar volume ratio between the third polymer block and the fourth polymer block is in a range of about 0.2:0.8 to about 0.35:0.65.

8. The method of claim 1, wherein the second polymer block has an affinity to the fourth polymer block that is greater than that between the second polymer block and the third polymer block.

9. The method of claim 8, wherein the first polymer block and the third polymer block are hydrophilic, and the second polymer block and the fourth polymer block are hydrophobic.

10. The method of claim 8, wherein the first polymer block and the third polymer block are hydrophobic, and the second polymer block and the fourth polymer block are hydrophilic.

11. The method of claim 1, wherein the first polymer block and the third polymer block comprise the same monomer, and the second polymer block and the fourth polymer block comprise the same monomer.

12. The method of claim 11, wherein the second block copolymer has a molecular weight that is lower than that of the first block copolymer.

13. The method of claim 12, wherein the molecular weight of the second block copolymer is about 0.2 to about 0.3 times that of the first block copolymer.

14. The method of claim 1, further comprising:
forming a neutral layer on the underlying layer before forming the block copolymer layer on the neutral layer and the underlying layer,
wherein the neutral layer has an affinity to the first polymer block that is substantially equal to an affinity of the neutral layer to the second polymer block, and the neutral layer has an affinity to the third polymer block that is substantially equal to an affinity of the neutral layer to the fourth polymer block.

15. The method of claim 1, further comprising:
forming a mask layer on the underlying layer before forming the block copolymer layer on the mask layer and the underlying layer;
etching the mask layer using the second block portion and the fourth block portions as etch masks to form a mask pattern; and
patterning the underlying layer using the mask pattern as an etch mask.

16. The method of claim 15, further comprising:
forming a neutral layer on the mask layer formed on the underlying layer before forming the block copolymer layer on the neutral layer, mask layer and underlying layer,
wherein the neutral layer has an affinity to the first polymer block that is substantially equal to an affinity of the neutral layer to the second polymer block, and the neutral layer has an affinity to the third polymer block that is substantially equal to an affinity of the neutral layer to the fourth polymer block.

17. A method for forming patterns of a semiconductor device, comprising:
forming a first pattern on an underlying layer, the first pattern having a first opening;
forming a block copolymer pillar to fill the first opening;
phase-separating the block copolymer pillar to form a pillar pattern and a surrounding pattern, the surrounding pattern having a second opening, the pillar pattern being formed in the second opening; and
removing the pillar pattern.

18. The method of claim 17, wherein forming the first pattern comprises:
forming a black copolymer layer on the underlying layer;
phase-separating the block copolymer layer to form the first pattern and a second pattern, the second pattern being formed in the first opening; and
removing the second pattern.

19. The method of claim 18, wherein the second pattern has pillar structure.

20. The method of claim 17, wherein the surrounding pattern contacts with an inner sidewall of the first opening.
